(19) United States
(12) Patent Application Publication
(10) Pub. No.: US 2025/0358972 A1
(43) Pub. Date: Nov. 20, 2025

(54) OPEN TOP CAGE RECEPTACLE ASSEMBLY

(71) Applicant: MELLANOX TECHNOLOGIES, LTD., Yokneam (IL)

(72) Inventors: Kfir Katz, Tivon (IL); Rom Becker, Ramat Yishai (IL); Yair Shoham, Yokneam Illith (IL); Michal Shlomai Hermon, Zikhron Ya’akov (IL); Ayal Shabtay, Haifa (IL); Erez Katz, Zur Yizhaq (IL)

(21) Appl. No.: 18/669,515

(22) Filed: May 20, 2024

(51) Int. Cl. H05K 7/20; H01R 12/70; H01R 13/508; H01R 13/516

(52) U.S. Cl. CPC H05K 7/20427; H01R 12/7005; H01R 13/508; H01R 13/516

(57) ABSTRACT

Apparatuses and associated methods of manufacturing are described that provide a cage receptacle assembly configured to receive a cable connector. The cage receptacle assembly includes a cage body defining a first end and a second end. The cage body includes a top cage member attached to a bottom cage member via two side portions, and the top cage member defines an opening. The cage receptacle assembly defines a heat dissipation unit disposed within the opening of the top cage member, allowing heat to be transferred from the cable connector to an external environment of the cage receptacle assembly.

### FIELD OF THE DISCLOSURE

The present disclosure is generally directed toward connector assemblies associated with optical, active, and high-powered cables used in conjunction with switch systems, modules, and other optical and electrical components. In particular, cages, shells, and housings of connector and receptacle assemblies are described which utilize heat dissipation units and elements that are configured to increase thermal performance.

### BACKGROUND

Datacenter switch systems and associated modules may include connections between other switch systems, servers, racks, and devices. Such connections may be made using cables, transceivers, cage receptacles, and connector assemblies, which may include a shell or housing configured to protect these connections from damage. Often, these cage receptacles can generate heat during operation, which can result in the failure of system components.

### BRIEF SUMMARY

Apparatuses and associated methods of manufacturing are described that provide a cage receptacle assembly configured to receive a cable connector. The cage receptacle assembly includes a cage body defining a first end and a second end. The cage body includes a top cage member attached to a bottom cage member via two side portions of the top cage member, and the top cage member defines an opening. The cage body can be constructed from a single piece of material (e.g., it may be integrally-formed) or may be constructed of multiple pieces that are attached together by at least one of welding, gluing, fastening, or the like. The cage receptacle assembly defines a heat dissipation unit disposed within the opening of the top cage member, wherein the heat dissipation unit directly contacts a port back shell. The heat dissipation unit may include one or more heat dissipation elements allowing heat to be transferred from the cable connector to an external environment of the cage receptacle assembly. The opening in the top cage member is enlarged for more efficient heat dissipation. For example, a pedestal in previous cage assemblies is omitted to permit direct contact between a connector and a heat dissipation unit.

The present disclosure relates in general to optical, active, and high-powered cables and associated connector assemblies used in conjunction with datacenter switch systems, modules, and other optical and electrical components. In particular, cages, shells, and housings of connector and receptacle assemblies are described which utilize heat dissipation units and elements that are configured to increase the thermal performance of connector assemblies.

Datacenter switch systems and associated modules may generally include connections between other switch systems, servers, racks, and devices. Such connections may be made using cables, transceivers, cage receptacles, and connector assemblies, which may include a shell or housing configured to protect these connections from damage. Often, these cage receptacles can generate heat during operation, which can result in the failure of system components.

Accordingly, the apparatuses and methods of manufacturing described herein provide a cage receptacle assembly configured to receive a cable connector. In some embodiments, the cage receptacle assembly may include a cage body defining a first end and a second end. The cage body may include a top cage member defined by a top portion and two side portions and a bottom cage member attached to the top cage member via the two side portions of the top cage member. The top cage member may define an opening. In embodiments, the cage body may be formed as a single part with a top, sides, and bottom. The cage body may define a receiving space configured to at least partially receive a cable connector therein via the first end such that a top surface of the cable connector is disposed proximate the top cage member and a bottom surface of the cable connector is disposed proximate the bottom cage member. The second end of the cage body may be configured to be received by a datacenter rack for enabling signals to pass between the cable connector that is at least partially received therein and the datacenter rack. A heat dissipation unit may be disposed within the opening in the top cage member. A second heat dissipation unit may be disposed within the opening in the bottom cage member Each heat dissipation unit may further include one or more heat dissipation elements (e.g., fins) configured to allow heat to be transferred from the cable connector that is at least partially received within the receiving space to an external environment of the cage receptacle assembly.

In embodiments, each heat dissipation unit may include one or more heat dissipation elements. The one or more heat dissipation elements may include fins or other structures to increase an overall surface area of the one or more heat dissipation elements.

In embodiments, the cage receptacle assembly may be attached to a printed circuit board assembly disposed adjacent to the bottom cage member. The printed circuit board assembly may also define a corresponding opening configured to substantially align with the opening defined by the bottom cage member. In embodiments, the bottom portion of the bottom cage member may define an opening configured to receive one or more additional heat dissipation units. For example, the heat dissipation unit is disposed within the opening defined by the bottom cage member may also be configured to be disposed within the corresponding opening of the printed circuit board assembly.

In other cases, in an instance in which the cable connector is at least partially received or fully received within the cage body, the cage receptacle assembly may further be configured such that the heat dissipation unit directly contacts the cable connector.

In embodiments, the bottom cage member may be integral to the top cage member.

In embodiments, the cage body is formed as a single piece. In other embodiments, the cage body is formed of two or more pieces that are connected or joined together.

In some further embodiments, the one or more heat dissipation elements may include fins. These fins may also be disposed substantially perpendicular with respect to the bottom cage member.

In some cases, the heat dissipation unit may include a first set of heat dissipation elements having a first height, and a second set of heat dissipation elements having a second height, wherein the second height is different than the first height. In such a case, the second height of the second set of heat dissipation elements may be greater than the first height of the first set of heat dissipation elements such that a portion of the second set extends through a plane defined by an inner surface of the heat dissipation unit corresponding to a location of the first set of heat dissipation elements.

In any of the above embodiments, the cable connector may be a quad small form factor pluggable cable connector.

In other embodiments, a method of manufacturing a cage receptacle assembly configured to receive a cable connector is provided. The method may include providing a top cage member defined by a top portion and two side portions and providing a bottom cage member. The method may include attaching the bottom cage member to the top cage member via the two side portions of the top cage member to form a cage body defining a first end and a second end. The cage body may define a receiving space configured to at least partially receive a cable connector therein via the first end such that a top surface of the cable connector is disposed proximate the top cage member and a bottom surface of the cable connector is disposed proximate the bottom cage member, and the second end may be configured to be received by a datacenter rack for enabling signals to pass between the cable connector that is at least partially received therein and the datacenter rack. The method may also include disposing a heat dissipation unit within an opening in the top and/or bottom cage member to allow heat to be transferred from the cable connector that is at least partially received within the receiving space to an external environment of the cage receptacle assembly.

In embodiments, the method may also include disposing a printed circuit board assembly adjacent the bottom cage member, and the printed circuit board assembly may define a corresponding opening configured to substantially align with the opening defined by the bottom cage member. In such an embodiment, the printed circuit board assembly adjacent the bottom cage member may be configured such the heat dissipation unit disposed within the opening defined by the bottom cage member is disposed within the corresponding opening of the printed circuit board assembly.

In other cases, in an instance in which the cable connector is at least partially received within the cage body, the cage receptacle assembly may be further configured such that the heat dissipation unit directly contacts the cable connector.

In embodiments, a cage receptacle assembly may be provided that includes a cage body defining a first end and a second end. The cage body may include a top cage member defined by a top portion and two side portions. The cage body may define a receiving space configured to at least partially receive a cable connector therein via the first end such that a top surface of the cable connector is disposed proximate the top cage member and a bottom surface of the cable connector is disposed proximate the bottom cage member, and the second end may be configured to be received by a datacenter rack for enabling signals to pass between the cable connector that is at least partially received therein and the datacenter rack.

Additional features and advantages are described herein and will be apparent from the following Description and the figures.

### BRIEF DESCRIPTION OF THE SEVERAL VIEWS OF THE DRAWINGS

Having thus described the disclosure in general terms, reference will now be made to the accompanying drawings, which are not necessarily drawn to scale:

FIG. 1 is a front perspective view of a rack of switch modules in a datacenter for use in accordance with some embodiments discussed herein;

FIG. 2A is a first perspective view of a cage receptacle assembly;

FIG. 2B is a second perspective view of a cage receptacle assembly;

FIG. 2C illustrates top and bottom views of one example of a cable connector;

FIGS. 3A-B provide various perspective views of cage receptacle assembly according to at least some embodiments of the present disclosure;

FIGS. 4A-B provide exploded views of a cage receptacle assembly according to at least some embodiments of the present disclosure;

FIGS. 5A-C provide various perspective views of a cage body in accordance with embodiments of the present disclosure;

FIGS. 6A-B provide various perspective views of a heat dissipation unit in accordance with embodiments of the present disclosure;

FIG. 7 provides a perspective view of a second heat dissipation unit in accordance with embodiments of the present disclosure;

FIG. 8A illustrates a cross-sectional view of a cage receptacle assembly; and

FIG. 8B illustrates a cross-sectional view of a cage receptacle assembly in accordance with embodiments of the present disclosure.

Like reference numbers and designations in the various drawings indicate like elements.

### DETAILED DESCRIPTION

The ensuing description provides embodiments only, and is not intended to limit the scope, applicability, or configuration of the claims. Rather, the ensuing description will provide those skilled in the art with an enabling description for implementing the described embodiments. It is understood that various changes may be made in the function and arrangement of elements without departing from the spirit and scope of the appended claims.

As used herein, the phrases “at least one,” “one or more,” “or,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C,” “A, B, and/or C,” and “A, B, or C” means A alone, B alone, C alone, A and B together, A and C together, B and C together, or A, B and C together.

Various aspects of the present disclosure will be described herein with reference to drawings that are schematic illustrations of idealized configurations.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and this disclosure.

As used herein, the singular forms “a,” “an,” and “the” are intended to include the plural forms as well, unless the context clearly indicates otherwise. It will be further understood that the terms “comprise,” “comprises,” and/or “comprising,” when used in this specification, specify the presence of stated features, integers, steps, operations, elements, and/or components, but do not preclude the presence or addition of one or more other features, integers, steps, operations, elements, components, and/or groups thereof. The term “and/or” includes any and all combinations of one or more of the associated listed items.

Embodiments of the present disclosure will now be described more fully hereinafter with reference to the accompanying figures. It should be appreciated that the present disclosure may be embodied in many different forms and should not be construed as limited to the embodiments set forth herein.

Like numbers refer to like elements throughout. As used herein, terms such as “front,” “rear,” “top,” etc. are used in the examples provided below to describe the position of certain components or portions of components in an installed and operational configuration. As used herein, the term “module” encompasses hardware, software and/or firmware configured to perform one or more particular functions, including but not limited to conversion between electrical and optical signals and transmission of the same. As would be evident to one of ordinary skill in the art in light of the present disclosure, the term “substantially” indicates that the referenced element or associated description is accurate to within applicable engineering tolerances.

As discussed herein, embodiments will be described with reference to a pluggable connector. It should be appreciated that embodiments of the present disclosure contemplate the use of any suitable pluggable connector. Non-limiting examples of suitable pluggable connectors that may be used in accordance with at least some embodiments include an octal small form factor pluggable (OSFP) connector or a quad small form factor pluggable (QSFP) connector. The embodiments of the present invention may be equally applicable for use with other types of connectors, which may include, without limitation, small form pluggable (SFP), C-form factor pluggable (CFP), and the like. Moreover, the embodiments of the present invention may also be used with any cable (e.g., passive copper cable (PCC), active copper cable (ACC), or the like) or interconnect utilized by datacenter racks and associated interconnect modules (e.g., an active optical module (AOM), QSFP transceiver module, OSFP transceiver module, or the like).

Additionally, as discussed herein, the embodiments are described with reference to a vertical-cavity surface-emitting laser (VCSEL) as an element of a transceiver system; however, embodiments of the present disclosure may be equally applicable for use with any transceiver system and/or element. Still further, as discussed herein, the example embodiment is described with reference to an interconnect module configured to receive a cage receptacle assembly to allow signals to pass between a cable connector and the interconnect module. The present disclosure, however, contemplates that a network interface, a high-capacity adapter, or any other applicable networking interface may equally be used instead or in conjunction with the interconnect module to receive the cage receptacle.

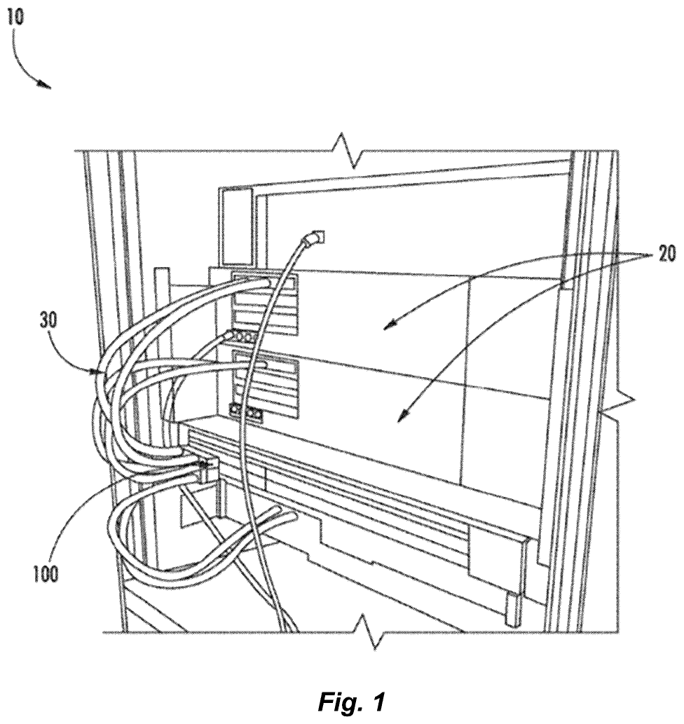

Extensive growth in global internet traffic due to increasing demands for high-definition video and high-speed broadband penetration has required new hardware that allows for higher data transmission rates in datacenters. These developments have resulted in the use of optical fibers offering enhanced capacity (e.g., greater bandwidth) over distance, increased bandwidth density, greater security and flexibility, and lower costs as compared to conventionally-used copper cables. A datacenter rack 10, or cabinet that is designed to house servers, networking devices, modules, and other datacenter computing equipment and used in conjunction with optical fibers, is depicted in FIG. 1.

Accordingly, various different types of cable connectors also exist for enabling transmission of signals (optical and/or electrical) between interconnect modules and other equipment in a datacenter. For example, QSFP connectors and cables, as well as other forms of connectors such as OSFP connectors, SFP connectors, CFP connectors, and OSFP transceivers provide high-speed information operations interface interconnects. Regardless of the type of cable connector, these transceivers may interface a switch system board, such as a motherboard in a switch system, to a fiber optic or copper networking cable, such as by making connections between interconnect modules 20 as shown in FIG. 1.

With continued reference to FIG. 1, for example, an interconnect module 20, which may house an application-specific integrated circuit (ASIC) as well as other internal components (not visible), is typically incorporated into a datacenter network via connections to other switch systems, servers, racks, and network components. Interconnect module 20 may, for example, interact with other components of the datacenter via external optical cables 30 and possible transceiver systems housed in the end of an optical cable 30. These optical cables 30 and transceivers may allow connections between an interconnect module and the other components of the datacenter network via cage receptacle assemblies 100.

The interconnect modules 20 may be configured to be received by the datacenter rack 10 and may be configured to allow for the conversion between optical signals and electrical signals. For example, optical cables 30 may carry optical signals as inputs to the interconnect module 20. The optical signals may be converted to electrical signals via an opto-electronic transceiver assembly, which may form part of the optical cable 30 in cases in which the optical cable 30 is an Active Optical Cable (AOC), such as a cable that includes a QSFP connector that is received by a port of an interconnect module 20. In other cases, the optical cable 30 may be passive, and the switch module 20 may include opto-electronic components that convert between optical signals and electrical signals. The electrical signals may then be processed by the interconnect module 20 and/or routed to other computing devices, such as servers and devices on other racks or at other datacenters via other components and cables (not shown). In addition, electrical signals received from other networking devices (e.g., from other datacenters, racks, etc.) may be processed by the interconnect module 20 and then converted into corresponding optical signals to be transmitted via the optical cables 30, going the opposite direction.

The transmission of data as electrical signals and the conversion between optical signals and electrical signals (e.g., via an AOC 30 and associated transceiver system or AOM) often results in the generation of heat by the components of the datacenter rack 10. As would be understood by one of ordinary skill in the art in light of the present disclosure, higher temperatures associated with such heat emissions can correspond to the increased likelihood of failure of electrical components and/or changes in the electrical and/or optical operating parameters of the components resulting in interference with the corresponding electrical and/or optical signals. Additionally, localization or concentration of higher temperatures in electrical components (e.g., the bottom surface of the AOC, AOM, QSFP, or OSFP cable connector) can result in a further increase in the likelihood of failure of electrical components located near the area of concentration.

Accordingly, embodiments of the invention described herein provide a cage receptacle assembly that is configured to provide improved thermal performance by enlarging the contact area between a connector and a heat dissipation unit(s) to more efficiently distribute heat and/or to more effectively dissipate the heat to the surrounding environment to maintain lower temperatures in the components.

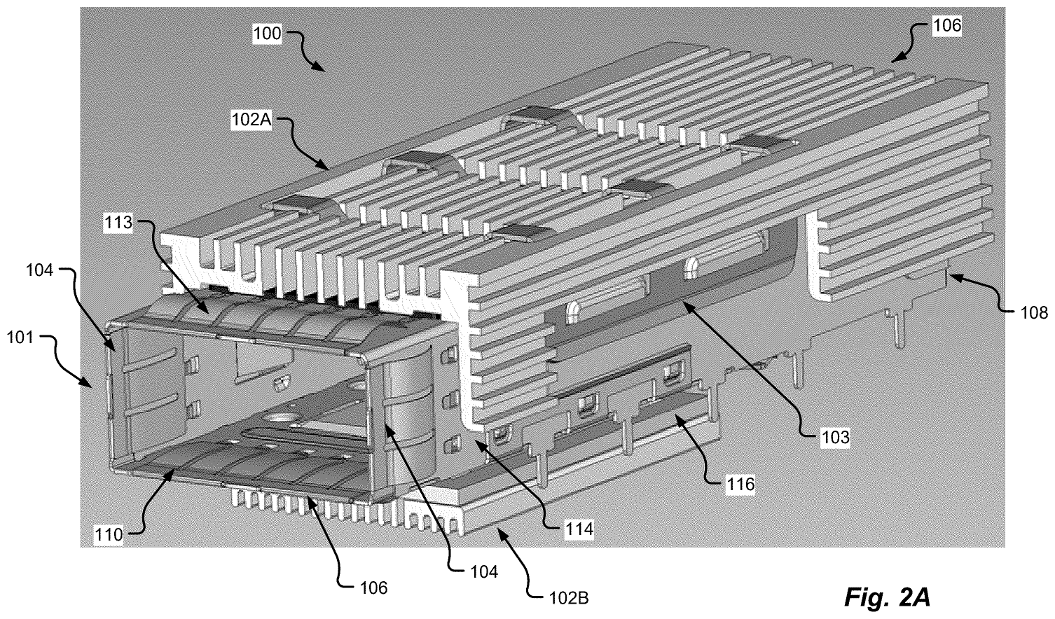

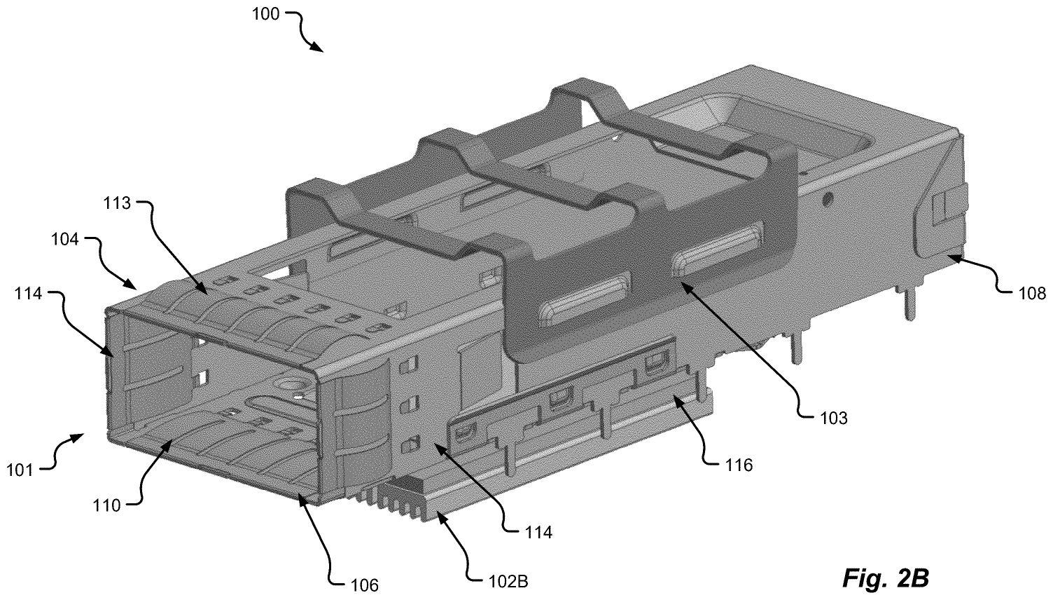

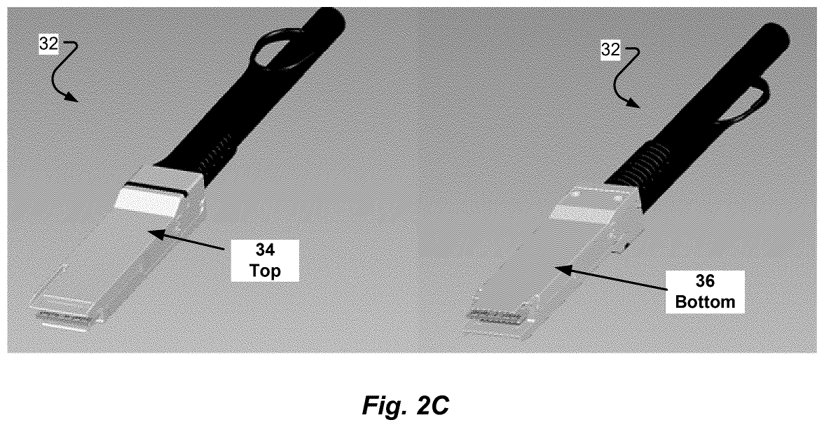

FIGS. 2A and 2B illustrate different views of an example of a cage assembly 100. In particular, FIG. 2A illustrates an example of a cage assembly 100 with a first heat dissipation unit 102A shown whereas FIG. 2B illustrates the cage assembly 100 with the first heat dissipation unit 102A removed, thereby providing a view of the underlying components. FIG. 2A further illustrates the spring(s) 103 that may be used to secure the first heat dissipation unit 102A to the cage body 101. The cage assembly 100 is also shown to include a second heat dissipation unit 102B, which is provided on an opposite side of the cage body 101 from the first heat dissipation unit 102A. The cage body 101 may be mounted to a printed circuit board (PCB) 116, which may include other optical and/or electrical components connected thereto (not shown). FIG. 2C illustrates an example cable connector 32 that may be used to interface and/or interconnect with the cage receptacle assembly 100.

The cage assembly 100 includes a cage body 101. The cage body 101 of the cage receptacle assembly 100 may be defined by a top cage member 104 that defines a top portion 113 and two side portions 114 that extend between the top portion 113 of the top cage member 104 to a bottom cage member 106. The top cage member 104 may be configured to attach to the bottom cage member 106 to form the cage body 101. The cage body 101 of the cage receptacle assembly 100 may be configured to at least partially receive a cable connector 32 (e.g., a QSFP or OSFP cable and/or connector) such that a top surface 34 of the cable connector 32 is disposed proximate the top cage member 104 and a bottom surface 36 of the cable connector 32 is disposed proximate the bottom cage member 106.

The cage receptacle assembly 100 may also define a first end 110 and a second end 108 opposite the first end 110, where the first end 110 is configured to receive the cable connector 32. For example, the first end 110 of the cage receptacle assembly 100 may be defined such that at least a portion of the cable connector 32 may be inserted into the cage receptacle assembly 100, or otherwise brought into engagement or contact with an inner surface of cage receptacle assembly 100 via the first end 110. The first end 110 may be configured to receive a cable connector 32 of any suitable dimension or of any type (e.g., AOC, Ethernet, Direct Attach Copper, etc.) such that the top cage member 104 is located proximate the top surface 34 of the cable connector 32 and the bottom cage member 106 is located proximate the bottom surface 36 of the cable connector 32.

By way of example, the first end 110 may be configured to receive a cable connector 32 corresponding to a QSFP cable connector, such that the QSFP cable connector is secured to the cage receptacle assembly 100 by engaging at least a part of the inner surface cage receptacle assembly 100 via the first end 110.

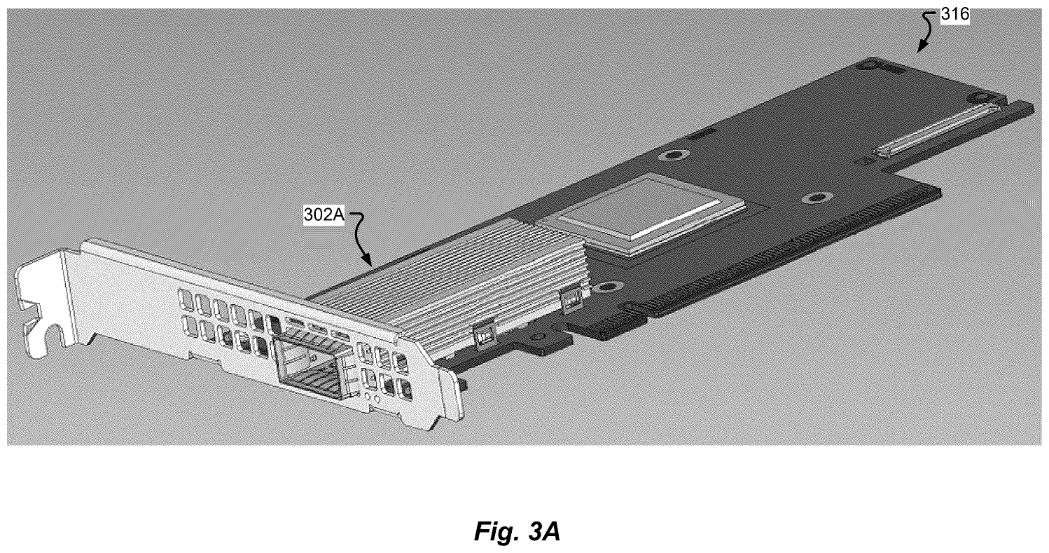

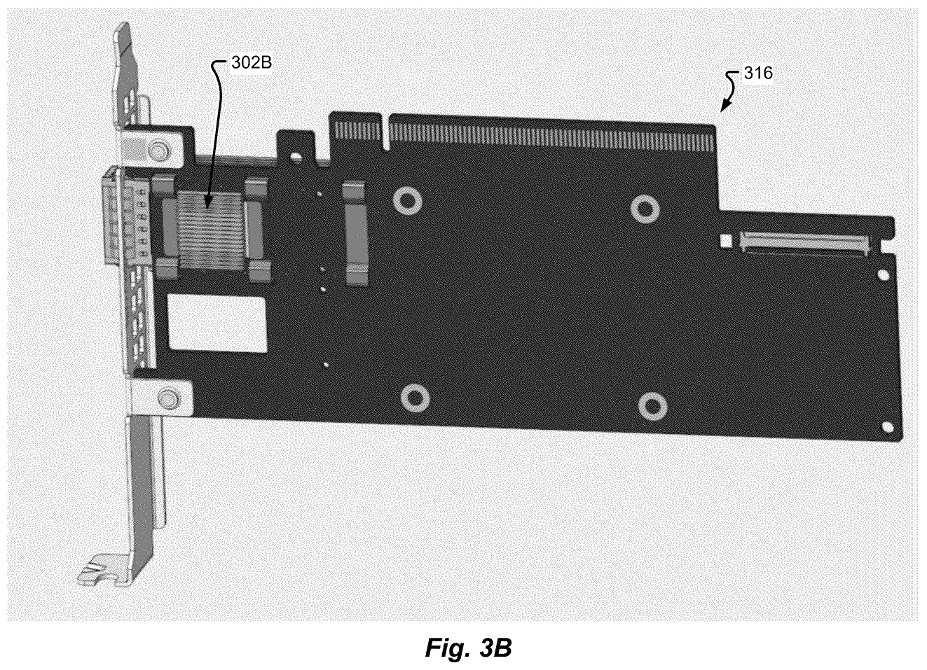

In a similar fashion and as will be described with reference to FIGS. 3A through 8B, embodiments of the present disclosure provide a cage body 401 having an opening at its first end 510 that is configured to receive a cable connector 32. As will be discussed in further detail herein, the opening in the first end 510 defined by the cage body 401 of the cage receptacle assembly 400 may be configured such that a cable connector 32 extends through the cage body 401 of the cage receptacle assembly 400. Specifically, the cable connector 32 may be configured (e.g., sized and shaped) such that upon engagement of a second end 508 of the cage receptacle assembly 400 with the module, the cable connector 32 may also engage the module such that electrical and/or optical signals may be transmitted between the cable 30 and module.

The cage receptacle assembly 100 may further define a second end 108 opposite the first end 110, where the second end 108 is configured to be received by an interconnect module for enabling signals to pass between the cable connector and a module. The cage receptacle assembly 100 may be configured to engage, or be secured to, a module (e.g., interconnect module 20 in FIG. 1). The cage receptacle assembly 100 may be configured such that the second end 108 defines at least one extension capable of being received by a datacenter interconnect module 20 (e.g., male to female connection).

By way of a more particular example, a QSFP cable connector may be received by the cage receptacle assembly 100 such that at least a portion of the QSFP cable connector is supported and/or surrounded by the cage body 101 of the cage receptacle assembly 100. The active end of the QSFP cable connector (e.g., the end configured to engage a module and allow electrical communication therethrough) may be positioned such that when the cage receptacle assembly 100 engages the module, the active end of the QSFP cable connector engages a corresponding port of the system to allow signals (e.g., electrical signals, optical signals, or the like) to travel between the QSFP cable connector and the interconnect module 20.

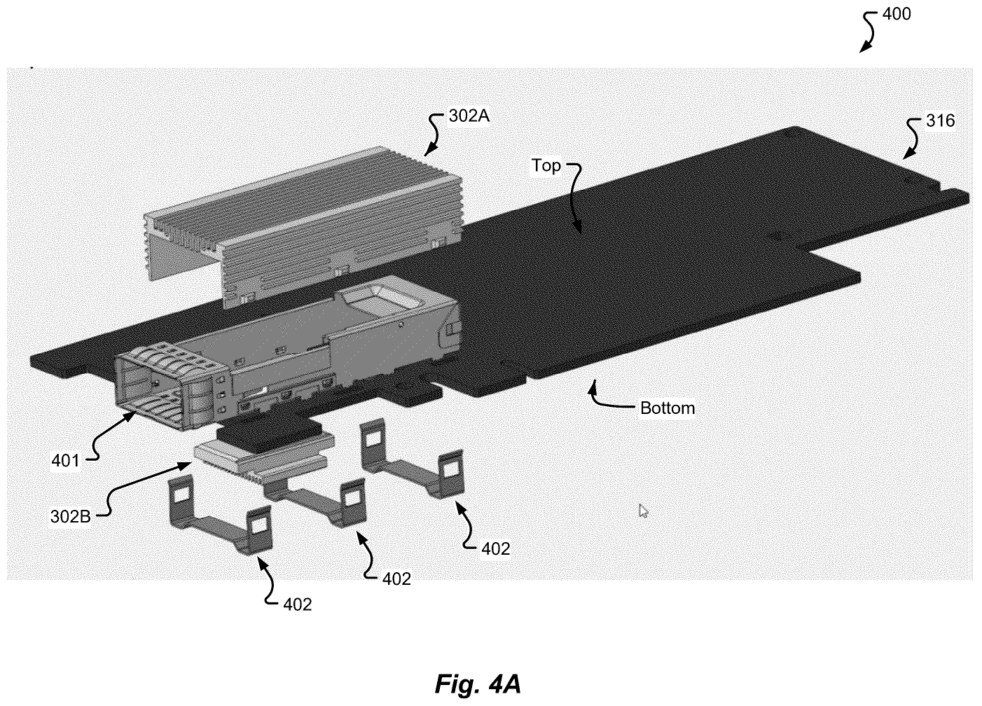

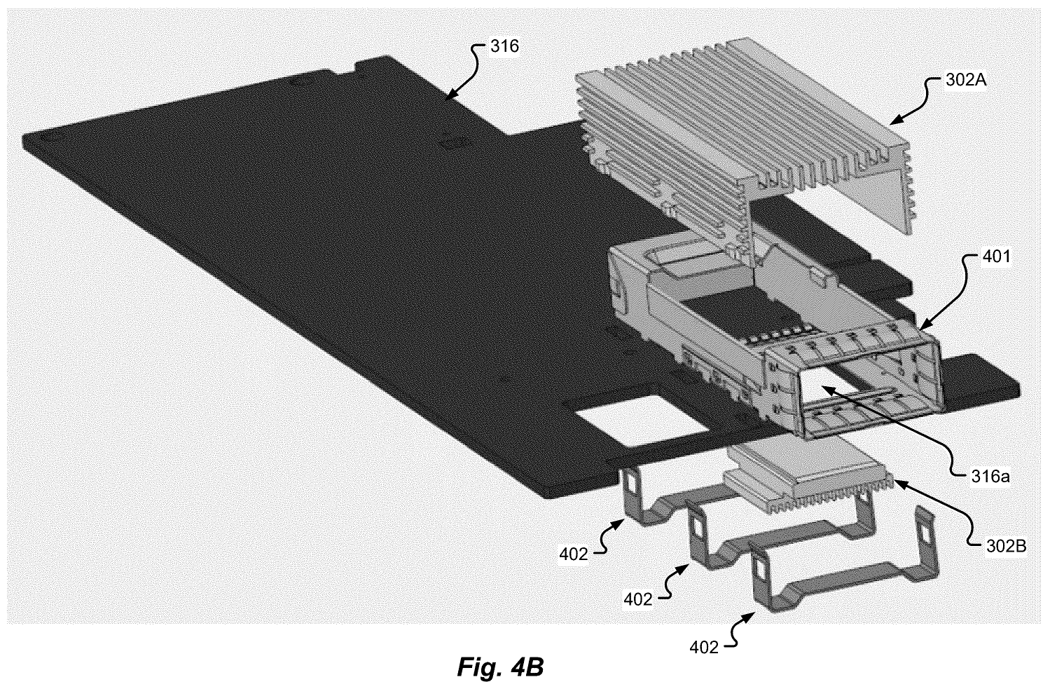

FIGS. 3A-B, illustrate a PCB 316 on which a cage assembly (e.g., cage body 401 in FIGS. 4A-B) may be disposed. In FIGS. 3A-B, the cage assembly is covered by a first heat dissipation unit 302A. The PCB 316 may be attached or otherwise secured to a cage body 401. In some embodiments, the cage body 401 may comprise one or more legs that extend through one or more holes in the PCB 316 to support an accurate positioning of the cage body 401 relative to the PCB 316. As would be understood by one of ordinary skill in the art in light of the present disclosure, the PCB 316 may include various optical and/or electrical components (e.g., passive circuit components, active circuit components, Integrated Circuit (IC) chips, ASICs, microprocessors, etc.). In some embodiments, the PCB 316 may include one or more transducers (e.g., vertical-cavity surface-emitting lasers (“VCSELs”)) configured to convert electrical signals into optical signals, and/or one or more photodiodes configured to convert optical signals into electrical signals.

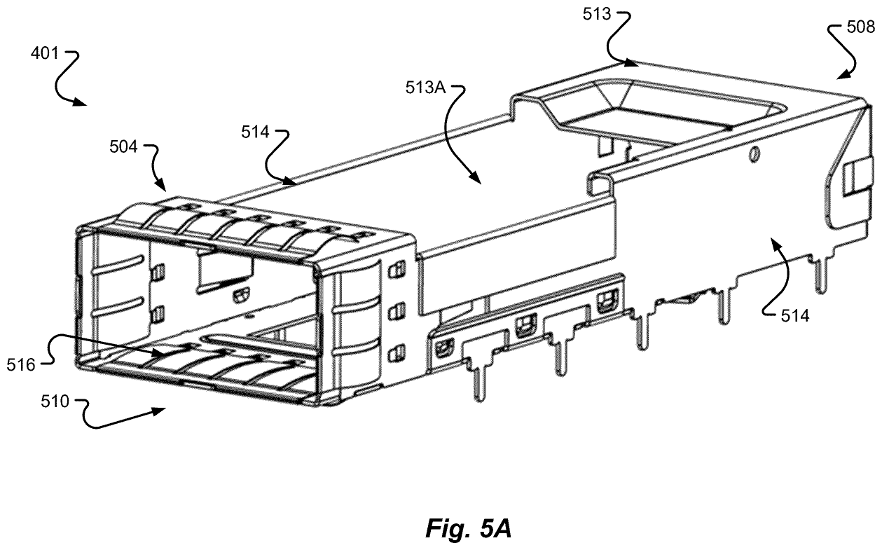

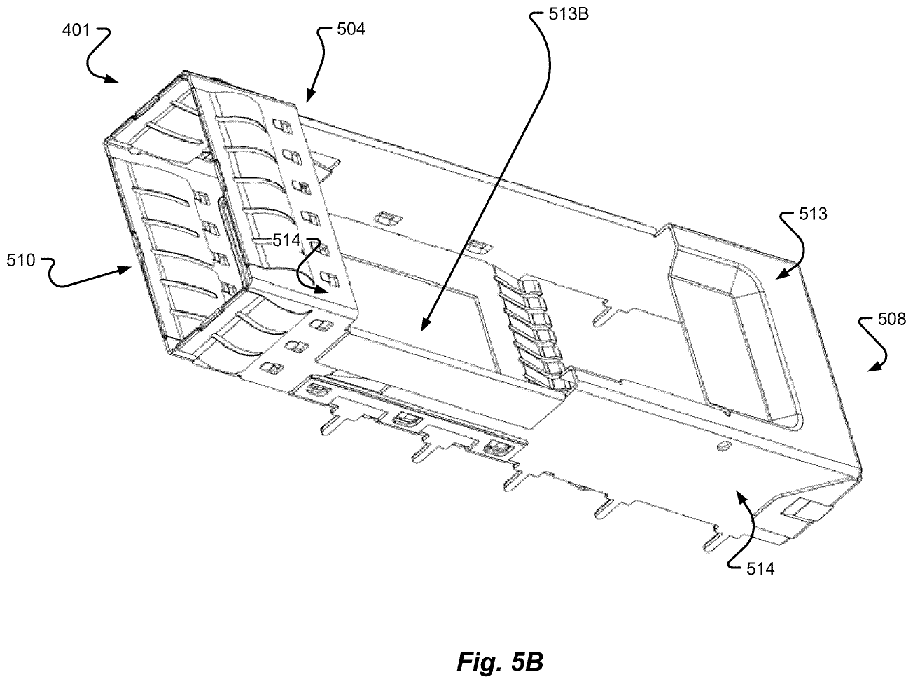

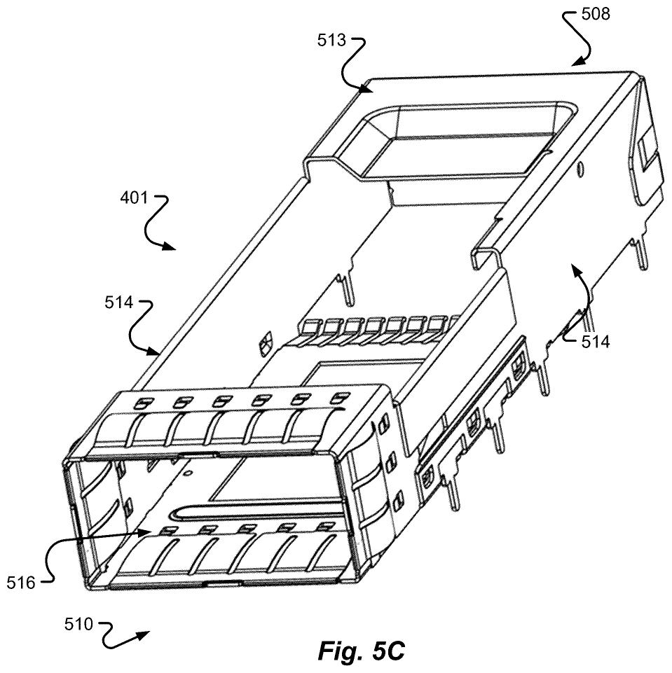

As shown in the exploded view of FIGS. 4A-B, the PCB 316 may define an opening 316a configured to substantially align with an opening 513B of the bottom cage member 516 illustrated in FIGS. 5A-B. A second heat dissipation unit 302B, described in greater detail below, may be received by the opening 513B and may be further configured to be disposed within the corresponding opening 316a of the PCB 316 when the second heat dissipation unit 302B is disposed within the opening 513B in the bottom of the cage body 401. A bottom view of the PCB 316 is illustrated in FIG. 3B helping to illustrate the second heat dissipation unit 302B positioned within the opening 513B of the cage body 401 and the opening 316a of the PCB 316.

It should be appreciated that the cage body 401 may be constructed of metal or a similar type of material. As some non-limiting examples, the cage body 401 may be formed of a sheet metal that is punched and folded to an appropriate form. Alternatively or additionally, the cage body 401 may be cast, milled, printed, or formed using any other suitable fabrication method.

As illustrated in the exploded views of FIGS. 4A-B, in embodiments in which a PCB 316 is disposed adjacent the bottom of the cage assembly 401, the second heat dissipation unit 302B may also be received by the corresponding opening 316a of the PCB 316. In such an embodiment, the second heat dissipation unit 302B may be dimensioned such that direct contact between the second heat dissipation unit 302B and the PCB 316 is precluded. Further, the dimensioning of the corresponding opening 316a may be such that the second heat dissipation unit 302B is fully received by the opening 513B of the bottom cage member. Said another way, the opening 316a may be dimensioned such that the PCB 316 does not inhibit contact between the second heat dissipation unit 302B and a cable connector 32 at least partially received by the cage receptacle assembly 100. For example, a width and length of the opening 316a may be configured to provide maximum contact between the heat dissipation unit 302B and the bottom side of cable connector received by the cage receptacle assembly 100.

The first heat dissipation unit 302A and/or second heat dissipation unit 302B may be configured to facilitate the transfer of heat from a cable connector 32 that is at least partially received within the cage body 401. One or both heat dissipation units 302A, 302B may be secured to the PCB 316 via one or more springs 402. Although the configuration of the cage receptacle assembly 400 is shown to include three springs 402, it should be appreciated that a greater or fewer number of springs 402 may be used to couple the heat dissipation unit(s) 302A, 302B to the cage body 401 as part of completing construction of the cage receptacle assembly 400. An advantage of using springs 402 is that the heat dissipation unit(s) 302A, 302B may be releasably coupled to the cage body 401, thereby allowing for an interchanging of components and/or modular replacement of components. The first heat dissipation unit 302A may be formed of a single piece of material (e.g., may be cast, molded, or otherwise formed from a single material). Alternatively, the first heat dissipation unit 302A may be formed of two or more pieces of material that are connected to one another (e.g., by welding, gluing, fastening, etc.). For instance, a top portion of the first heat dissipation unit 302A may correspond to a first piece of material that is connected to two discrete side portions to form the U-shaped configuration shown in FIG. 4A. The first heat dissipation unit 302A and/or second heat dissipation unit 302B may be constructed from any suitable material that is capable of transferring thermal energy. Non-limiting examples of materials that may be used to form the heat dissipation unit(s) 302A, 302B include metal materials (e.g., gold, silver, Aluminum, copper, etc.), ceramic materials, graphite, metal alloys, silicon carbide, etc.

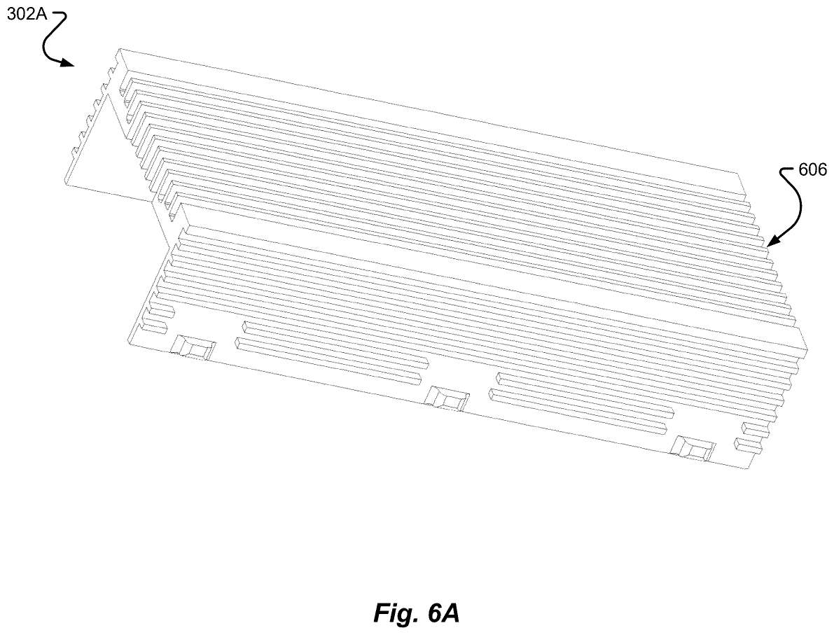

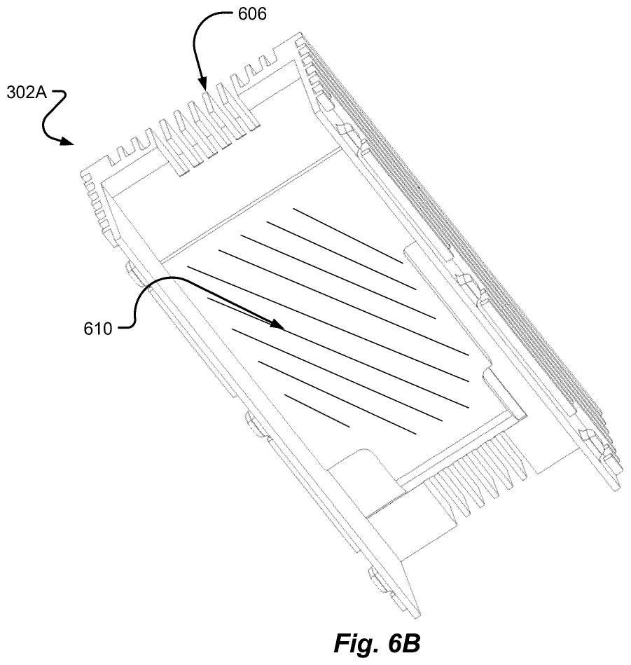

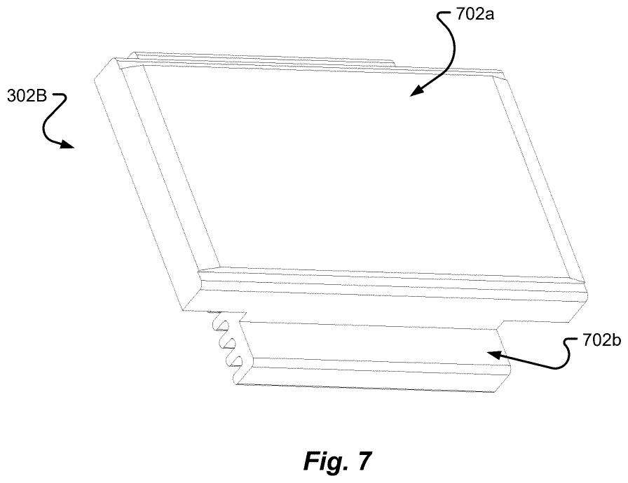

As can be seen in FIG. 6A, the first heat dissipation unit 302A may, for example, define heat dissipation elements 606 (e.g., fins), which extend substantially perpendicularly outwardly. The heat dissipation elements 606 may, in some embodiments, define a plurality of fins having rectangular cross-sections. While the description herein refers to the heat dissipation elements 606 configured as pins or fins, the present disclosure contemplates that any extension having any cross-sectional shape may be used as the heat dissipation elements 606. Furthermore, the present disclosure contemplates that any number of heat dissipation elements may be defined by the heat dissipation units 302A-B and may be positioned at any angle and/or arrangement. The heat dissipation elements 606 may be configured to extend the overall surface area of the first heat dissipation unit 302A. As shown in FIG. 7, the second heat dissipation unit 302B may also include fins or similar structures to enhance the overall surface area of the second heat dissipation unit 302B.

The one or more heat dissipation elements 606 (e.g., the pluralities of fins) may facilitate the transfer of heat from the cable connector 32 to an external environment of the cage receptacle assembly 400 by increasing the convective cooling experienced by the cage receptacle×the rate of heat transfer to an external environmental via the increased surface area provided by the heat dissipation elements 606 in the portion of the cage receptacle assembly 400 contacting the external environment. In other words, by utilizing a heat dissipation units 302A-B including heat dissipation elements 606 (e.g., a plurality of fins), the cage receptacle assembly 400 may increase its surface area for heat dissipation such that a larger area is in contact with the air of its external environment (e.g., the air from the environment that is contained and/or flowing through the one or more heat dissipation elements 606). As such, air traveling between and around the one or more heat dissipation elements 606 is able to receive more heat transferred from the body of the cage receptacle assembly 400 than it would have otherwise if contacting a single, flat surface. As a result, the temperature of the heat dissipation units 302A-B (e.g., at the ends of the pluralities of fins) should remain lower than the temperature of the rest of the cage body 401 of the cage receptacle assembly 400 (e.g., the combined top cage member and bottom cage member) to provide a larger temperature gradient between these surfaces, thereby serving as a heat sink. The resultant temperature gradient also facilitates transfer of heat from the cage receptacle assembly 400 and optical connector cable to the external environment.

As would be understood by one of ordinary skill in the art in light of the present disclosure, with reference to FIGS. 6A-B, the one or more heat dissipation elements 606 (e.g., the pluralities of fins) may improve heat dissipation from the cage receptacle assembly 400 by providing contact between a contact surface of the heat dissipation units 302A-B and the cable connector that is at least partially received within the cage receptacle assembly 400. With reference to FIGS. 5-6, the openings 513A-B may be configured such that each respective heat dissipation unit(s) 302A, 302B contacts a surface of a cable connector when the connector is at least partially received by the cage receptacle assembly 400. In particular, as shown in FIG. 6B, a contact portion 610 of the first heat dissipation unit 302A may be configured to directly contact the cable connector 32 when the cable connector 32 is received in the cage receptacle assembly 400 (e.g., inserted into the cage body 401). The contact portion 610 may protrude relative to the other bottom-facing surfaces of the first heat dissipation unit 302A. In some embodiments, the contact portion 610 may comprise a conductive material (e.g., a thermal interface material (TIM) such as a phase-change material or the like).

By increasing the contact area between elements (e.g., between a surface of the cable connector and heat dissipation unit(s) 302A, 302B) heat may more freely transfer between the connector assembly and the cable connector. In particular, the density of atoms found in solid materials is considerably larger than the density of atoms found in gases. This larger atomic density encourages heat transfer due to increased contact at an atomic level. Therefore, increasing the contact area between solid elements as opposed to gases disposed between the cage body 401 of the cage receptacle assembly 400 and the cable connector may improve the heat transfer to an external environment.

The heat dissipation unit(s) 302A and/or 302B may be covered (partially or completely) with a conductive material (e.g., a TIM such as a phase-change material or the like). Further, as discussed above, these one or more additional heat dissipation unit(s) 302A, 302B may be secured to the cage receptacle assembly 400 via a plurality of spring-assisted contact flanges. Illustratively, and without limitation, arms of the springs 402 may extend from a bottom of the PCB 316 through one or more holes in the PCB 316. The arms of the springs 402 may flex around and secure the first heat dissipation unit 302A to the cage body 401. Each spring 402 may also include a bridge portion that connects the arms of the springs 402. The bridge portion may contact the bottom of the PCB 316 and/or the second heat dissipation unit 302B to secure the position of the first heat dissipation unit 302A and the second heat dissipation unit 302B relative to the cage body 401.

FIGS. 5A-C illustrate a cage body 401 of a cage assembly. The cage body 401 of the cage receptacle assembly may be defined by a top portion 513 and two side portions 514 that extend between the top portion 513 and a bottom portion to form the cage body 401. The cage body 401 of the cage receptacle assembly may be configured to at least partially receive a cable connector 32 (e.g., a QSFP or OSFP cable and/or connector) such that a top surface 34 of the cable connector 32 is disposed proximate the top portion 513 and a bottom surface 36 of the cable connector 32 is disposed proximate the bottom portion. The cage body 401 has an enlarged opening in the top portion 513.

The cage body 401 may also define a first end 510 and a second end 508 opposite the first end 510, where the first end 510 is configured to receive a cable connector. For example, the first end 510 of the cage body 401 may be defined such that at least a portion of the cable connector may be inserted into the cage receptacle assembly, or otherwise brought into engagement or contact with an inner surface of cage receptacle assembly via the first end 510. The first end 510 may be configured to receive a cable connector of any dimension or of any type (e.g., AOC, Ethernet, Direct Attach Copper, etc.) such that the top cage member 504 is located proximate the top surface of the cable connector and the bottom cage member 516 is located proximate the bottom surface of the cable connector. By way of example, the first end 510 may be configured to receive a cable connector 32 corresponding to a QSFP cable connector, such that the QSFP is secured to the cage receptacle assembly by engaging at least a part of the inner surface cage receptacle assembly via the first end 510.

The cage receptacle assembly may further define a second end 508 opposite the first end 510, where the second end 508 is configured to be received by a module for enabling signals to pass between the cable connector and a module. The cage receptacle assembly may be configured to engage, or be secured to, a module (e.g., the interconnect module 20 in FIG. 1). The cage body 401 may be configured such that the second end 508 defines at least one extension capable of being received by a datacenter interconnect module 20 (e.g., male to female connection). As discussed above, the opening defined by the cage body 401 is such that an active end of a cable connector may extend through the cage body 401. Specifically, the active end of the cable connector may be configured (e.g., sized and shaped) such that upon engagement of the second end 508 of the cage receptacle assembly with the module, the active end of the cable connector may also engage the module such that signals may be transmitted between the cable and module.

FIG. 7 illustrates additional details of the second heat dissipation unit 302B. The second heat dissipation unit 302B is disposed on the bottom side of the PCB 316 within the opening 316a. In some embodiments, the second heat dissipation unit 302B further comprises a first portion 702a and a second portion 702b, wherein the first portion 702a is above the second portion 702b. In embodiments, the first portion 702a has a smaller surface area than the second portion 702b. When disposed on a bottom side of the PCB 316, the first portion 702a of the bottom heat dissipation unit 302B extends through the opening 316a in the PCB 316 and is arranged adjacent to the bottom surface 36 of the cable connector 32.

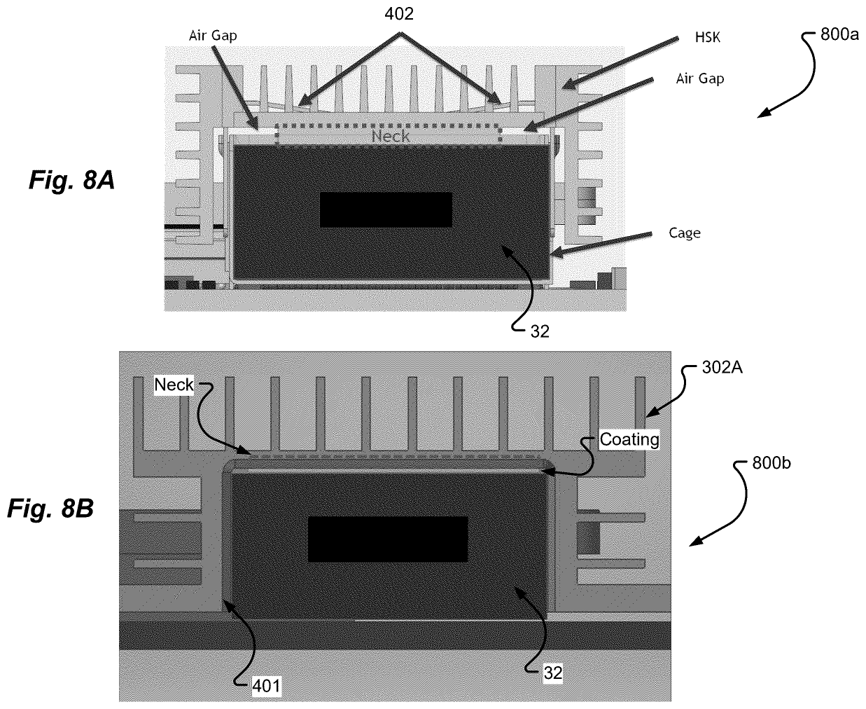

FIG. 8A illustrates a cross-sectional view of a traditional cage receptacle assembly 800a. As illustrated in FIG. 8A, the traditional cage receptacle assembly 800a has a smaller neck and air gaps between the heat dissipation unit (HSK) and the top of the connector 32. FIG. 8B illustrates a cross-sectional view of a cage receptacle assembly 800b according to at least some embodiments of the present disclosure. As illustrated in FIG. 8B, the cage receptacle assembly 800b has an enlarged contact area (e.g., neck). Optionally, the cage receptacle assembly 800b includes a coating (e.g., a TIM such as a phase-change material) on the heat dissipation unit 302A that improves contact resistance. Additionally, the cage receptacle assembly 800b does not require springs.

The present disclosure contemplates that the present invention may be created from any suitable material known in the art (e.g., carbon steel, aluminum, polymers, ceramics, and the like), particularly materials possessing high thermal conductivity. By way of example, the cage receptacle assembly 100 may be created by an extrusion and/or machine process. In such an example, a single body of fixed cross-sectional area may be produced by an extrusion process. This single body may be created via pushing a base material (e.g., a polymer) through a dimensioned die such that the cage body 101 of the cage receptacle assembly is created. In some embodiments, the single body may be created as two separate elements (e.g., a top cage member and bottom cage member) where the two separate elements are further attached to form the single body. This extruded body may then be modified through a machine process whereby material is removed from the extruded body to create the finished cage receptacle assembly 100. The machining process may include any or all of micro machining, turning, milling, drilling, grinding, water jet cutting, EDM, EDM, AFM, USM, CNC, and the like, in any order or combination. Although described as an extrusion and machine process of a single piece of material, any portion or sub-portion of the cage receptacle assembly 100 may be separately formed or attached without departing from the scope of this disclosure.

Many modifications and other embodiments of the inventions set forth herein will come to mind to one skilled in the art to which these inventions pertain having the benefit of teachings presented in the foregoing descriptions and the associated drawings. Although the figures only show certain components of the apparatus and systems described herein, it is understood that various other components (e.g., components of printed circuit boards, transceivers, cables, etc.) may be used in conjunction with the cage receptacle assembly. Therefore, it is to be understood that the inventions are not to be limited to the specific embodiments disclosed and that modifications and other embodiments are intended to be included within the scope of the appended claims.

It is to be appreciated that any feature described herein can be claimed in combination with any other feature(s) as described herein, regardless of whether the features come from the same described embodiment.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. A cage receptacle assembly configured to receive a cable connector, the cage receptacle assembly comprising:
a cage body defining a first end and a second end, wherein the cage body comprises:
a top cage member defined by a top portion and two side portions, wherein the top cage member defines a top opening;
a bottom cage member coupled to the top cage member via the two side portions of the top cage member, wherein the bottom cage member is positioned adjacent to a printed circuit board (PCB) assembly; and
a heat dissipation unit disposed proximate to the top opening of the top cage member, wherein the heat dissipation unit is mounted relative to the top cage member such that the heat dissipation unit directly contacts the cable connector when the cable connector is received in the cage receptacle assembly.

2. The cage receptacle assembly according to claim 1, wherein the heat dissipation unit is coated with a conductive material.

3. The cage receptacle assembly according to claim 2, wherein the conductive material comprises a thermal interface material (TIM).

4. The cage receptacle assembly according to claim 1, wherein the bottom cage member defines a bottom opening.

5. The cage receptacle assembly according to claim 1, further comprising:
one or more springs to secure the heat dissipation unit to the cage body.

6. The cage receptacle assembly according to claim 1, wherein the cable connector is pluggable into the first end of the cage body.

7. The cage receptacle assembly according to claim 1, wherein the cage body is configured to receive a quad small form factor pluggable (QSFP) connector.

8. The cage receptacle assembly according to claim 1, wherein the cage body is configured to receive an octal small form factor pluggable (OSFP).

9. The cage receptacle assembly according to claim 1, wherein the cage body comprises metal.

10. The cage receptacle assembly according to claim 9, wherein the cage body is formed of sheet metal that is folded and punched.

11. The cage receptacle assembly according to claim 9, wherein the cage body is formed by at least one of casting, milling, and printing.

12. The cage receptacle assembly according to claim 1, further comprising:
a second heat dissipation unit disposed on a bottom side of the PCB.

13. The cage receptacle assembly according to claim 12, further comprising:
one or more springs to secure the heat dissipation unit and the second heat dissipation unit to the cage body.

14. The cage receptacle assembly according to claim 13, wherein the one or more springs comprise at least one arm to wrap around the two side portions of the top cage member.

15. The cage receptacle assembly according to claim 1, wherein the heat dissipation unit comprises one or more fins.

16. The cage receptacle assembly according to claim 1, wherein the top cage member and the bottom cage member are formed from a single piece of material.

17. The cage receptacle assembly according to claim 1, wherein the top portion and two side portions of the cage body are formed from a single piece of material.

18. The cage receptacle assembly according to claim 1, wherein the top cage member is formed from two or more pieces of material.

19. A cage receptacle assembly, comprising:
a cage body defining a first end and a second end, wherein a top portion of the cage body comprises a top opening and wherein a bottom portion of the cage body is positioned adjacent to a printed circuit board (PCB); and
a heat dissipation unit disposed proximate to the top opening such that the heat dissipation unit directly contacts a cable connector when the cable connector is received in the first end of the cage body.

20. A cage receptacle assembly, comprising:
a cage body defining a first end and a second end, wherein a top portion of the cage body comprises a top opening and wherein a bottom portion of the cage body is positioned adjacent to a printed circuit board (PCB);
a heat dissipation unit disposed proximate to the top opening such that the heat dissipation unit directly contacts a cable connector when the cable connector is received in the first end of the cage body; and
one or more springs that retain a position of the heat dissipation unit relative to the cage body.
